(19) United States
(12) Patent Application Publication
(10) Pub. No.: US 2006/0091293 A1
(43) Pub. Date: May 4, 2006

(54) Opto-electronic device having a light-emitting diode and a light sensor

(75) Inventors: Heinrich Grueger, Dresden (DE); Torsten Schneider, Putzham (DE); Joerg Amelung, Dresden (DE); Bodo Sauer, Weinbohla (DE)

Correspondence Address: M. Paul Qualey, Esq.;Thomas, Kayden, Horstemeyer & Risley, LLP, Suite 1750, 100 Gallervia PKWY., NW., Atlanta, GA, 30339-5948, US

(73) Assignee: FRAUNHOFER-GESELLSCHAFT ZUR FOERDERUNG DER ANGEWANDTEN FORSCHUNG, E.V.

(21) Appl. No.: 11/283,147

(22) Filed: Nov. 18, 2005

Related U.S. Application Data
(63) Continuation of application No. PCT/EP03/05253, filed on May 19, 2003.

(51) Int. Cl. G01J 1/42

(52) U.S. Cl. 250/208.6

(57) ABSTRACT

An opto-electronic device includes a substrate, a light sensor and a light-emitting diode having a light-emitting layer of an organic material, wherein the light sensor and the light-emitting diode are monolithically integrated with the substrate.

### CROSS-REFERENCE TO RELATED APPLICATIONS

This application is a continuation of co-pending International Application No. PCT/EP2003/005253, filed May 19, 2003, which designated the United States and was not published in English.

### BACKGROUND OF THE INVENTION

1. Field of the invention

The present invention relates to an opto-electronic device having a light-emitting diode and a light sensor in particular usable for detecting a path length, an angle of rotation, a distance or a position, and to a method for manufacturing the same.

2. Description of the Related Art

In numerous fields of the art, opto-electronic devices or systems, respectively, are used to detect distances, path lengths, angles of rotation, positions and other variables. To this end, in particular opto-electronic devices are used which include a light source or radiation source, respectively, and a light sensor or a light-sensitive detector, respectively.

Light emitted from the light source is directed from an optical device onto the light sensor. The optical device is, for example, a reflector, a mirror or another reflecting device, an optical grating or another light-diffracting means. The intensity of the light received by the light sensor depends on the distance of the optical device from the opto-electronic device or on its spatial orientation. From the light received by the light sensor, thus the distance, the location or the spatial orientation of the optical device in relation to the opto-electronic device may be derived.

In some applications, no optical device is used but the light emitted from the light-emitting diode is reflected by an object to be detected. From the reflected light received from the light sensor location, arrangement, size or other characteristics of the object may be concluded. One example is the “out of position” detection of a passenger in an automobile in relation to an airbag.

Frequently, photodiodes, phototransistors, photoresistors or similar semiconductor devices are used as light sensors. Instead of a single light sensor frequently several light sensors are used which may be arranged in a one-dimensional way as a row or in a two-dimensional way as an array. The use of several light sensors enables a detection of simple geometric images or also of diffraction or interference patterns.

As light sources, frequently light-emitting diodes (LEDs) are used. In order to differentiate light emitted from the light source and directed to the light sensor from light of a different origin, the light source frequently emits a characteristic signature or a light signal, respectively, having a time-dependence known to evaluation electronics downstream from the light sensor.

The technologically most simple and easiest realization of an opto-electronic device having a light sensor and a light source is the setup of the corresponding transmitter and detector structures from discrete devices on a board. With regard to manufacturing technology, this realization is very expensive, however. Further, a miniaturization is only restrictedly possible even when using surface-mounted devices.

In particular opto-electronic devices to be manufactured in a greater number or more strongly miniaturized are therefore generally realized with an arrangement as it is described in DE 19720300 A1. This arrangement allows a substantially smaller opto-electronic device that may be mounted with less effort. FIG. 2 is a schematic illustration of a section through an opto-electronic device as it is described in DE 19720300. An Si substrate or chip 10, respectively, comprises a depression or recess 14, respectively, at a surface 12. In the recess 14 an SMD light-emitting diode 16 is arranged as a light source of the opto-electronic device. At the surface of the substrate 10 outside the recess 14 a plurality of light-sensitive diodes 18 are arranged as light sensors. The SMD light-emitting diode 16 and the light-sensitive diodes 18 are connected to conductive traces or contacted through conductive traces, respectively, in order to feed and tap electrical signals. The SMD light-emitting diode 16 is connected to a conductive trace 22 via one or several bond wires 20.

One disadvantage of the conventional opto-electronic device illustrated with reference to FIG. 2 is that the generation of the pit or recess 14, respectively, requires special or additional process steps, respectively. This increases the manufacturing costs and, like every process step, the probability of a defect, and thus the waste material of the production. A further disadvantage is that a metallization or the generation of a conductive trace in the recess 14, respectively, is, for example, critical for contacting the side of the SMD light-emitting diode 16 facing the Si substrate 10. Further, the requirement with regard to precision is high when mounting the SMD light-emitting diode 16 in the recess 14. The one or several bond wires 20 necessary for contacting the SMD light-emitting diode 16 require mounting space and in particular project into the half-space bounded by the plane of the surface 12 and opposing the Si substrate 10. By this, the minimum possible distance between the opto-electronic device and its surface 12 on the one hand and the optical device or the reflecting object on the other hand is bounded. Further, depending on the precision achieved when mounting the SMD light-emitting diode 16, a calibration of the system is required. A functional test is only possible after completing the system or the opto-electronic device, respectively.

### SUMMARY OF THE INVENTION

It is the object of the present invention to provide an opto-electronic device and a method for manufacturing the same and an optical sensor facilitating manufacturing with little effort.

In accordance with a first aspect, the present invention provides an opto-electronic position or angle detector, having a substrate; a light-emitting diode having a light-emitting layer of an organic material; a plurality of light sensors arranged laterally adjacent to the light-emitting diode, wherein the light sensors and the light-emitting diode are monolithically integrated with the substrate; and an optical device arranged opposite the light sensors and the light-emitting diode for directing light emitted from the light-emitting diode to the light sensors, wherein a characteristic of the light received from the light sensors is dependent on the location or the alignment or of a characteristic of the optical device.

The present invention provides an opto-electronic device having a substrate, a light sensor and a light-emitting diode comprising a light-emitting layer of an organic material, wherein the light sensor and the light-emitting diode are monolithically integrated with the substrate.

According to a special aspect, the present invention provides an optical sensor comprising an inventive opto-electronic device and an optical device arranged opposite the light sensor and the light-emitting diode for directing light emitted by the light-emitting diode towards the light sensor, wherein one characteristic of the light received from the light sensor is dependent on the location or the alignment of the optical device.

Further, the present invention provides a method for manufacturing an opto-electronic device, comprising the following steps:

providing a substrate;

generating a light sensor at the substrate; and

generating a light-emitting diode comprising a light-emitting layer of an organic material at the substrate,

wherein the light sensor and the light-emitting diode are monolithically integrated with the substrate.

The present invention is based on the idea of monolithically integrating an organic light-emitting diode or a light-emitting diode having a light-emitting layer of an organic material, respectively, and a light sensor on a substrate, in particular on a semiconductor substrate or on a chip, respectively.

One advantage of the present invention is that the opto-electronic device may be manufactured with low manufacturing expense and thus easily in large numbers. In particular, the manufacturing of the inventive opto-electronic device requires no generation of a recess as it is required according to the prior art. The manufacturing of the inventive opto-electronic device is thus performed using known and well-controlled semiconductor technologies and using available devices or available equipment, respectively.

The manufacturing is simplified by the fact that it requires no generation of a metallization in a recess. Further, any process steps for generating, metallizing and passivating a recess are omitted.

For contacting the light-emitting diode, preferably conductive traces are used. Bond wires are not required. Compared to the prior art, in the manufacturing of the inventive opto-electronic device any working steps for mounting the SMD light-emitting diode are omitted.

The lateral precision of the manufacturing and the arrangement of the light-emitting diode correspond to the accuracy of a semiconductor manufacturing process. This is typically below the micrometer scale and is thus better by a factor of 10 to 100 than in the conventionally required mounting of the SMD light-emitting diode whose lateral position inaccuracy is always several 10 μm. Further, steps for the adjustment or calibration of the mounting position of the conventional SMD light-emitting diode 16 are omitted.

It is a further advantage of the present invention that the building height of a light-emitting diode having a light-emitting layer of an organic material comprising 150 nm to 160 nm is extremely small. The organic light-emitting diode is thus thinner than passivation layers across conductive traces of a semiconductor chip.

A further important advantage of the present invention is that the opto-electronic device is completed fully on wafer level or before dicing. The opto-electronic device may thus be tested in the wafer arrangement which enables a cost-effective manufacturing, in particular with large numbers.

Due to the omission of bond wires, the inventive opto-electronic device may be implemented very flat and may be brought a lot closer to an object.

It is a further advantage of the present invention that the inventive opto-electronic device may replace a conventional opto-electronic device without changes of an upstream or a downstream system being required. The present invention thus significantly reduces the development and manufacturing requirements.

One main aspect of the present invention is the combination of light sensors which are preferably semiconductor light sensors having an organic light-emitting diode or a light-emitting diode having a light-emitting layer of an organic material, respectively. The present invention thus combines the simple and well-controlled technology of generating semiconductor light sensors, for example photodiodes, phototransistors or photoresistive devices, with the advantages of the organic light-emitting diode that may be manufactured in a simple way.

Preferred implementations of the present invention are defined in the sub-claims.

### BRIEF DESCRIPTION OF THE DRAWINGS

Preferred embodiments of the present invention are explained in more detail in the following with reference to the accompanying drawings, in which:

FIG. 1 shows a schematic, perspective illustration of an opto-electronic device according to a preferred embodiment of the present invention; and

FIG. 2 shows a schematic illustration of a section through a conventional opto-electronic device.

### DESCRIPTION OF THE PREFERRED EMBODIMENTS

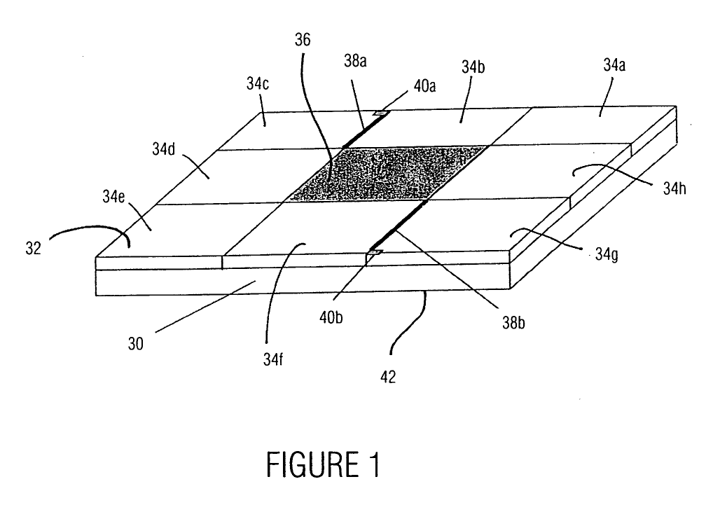

FIG. 1 is a schematic illustration of a perspective view of an opto-electronic device according to a preferred embodiment of the present invention. An Si substrate 30 comprises eight light sensors 34a, . . . , 34h and a light-emitting diode 36 on one surface 32. The light sensors 34a, . . . , 34h and the light-emitting diode 36 respectively comprise a substantially rectangular or square shape. The light sensors 34a, . . . , 34h and the light-emitting diode 36 are arranged in a grid-like shape of three rows lying next to each other respectively having three devices, wherein the light-emitting diode 36 is in the middle and is surrounded by the light sensors 34a, . . . , 34h on all sides. The light sensors 34a, . . . , 34h are preferably semiconductor light sensors, for example photodiodes, phototransistors, photoresistive devices or other photosensitive devices having an electrical characteristic which is changed by incoming light in a known way.

The light-emitting diode 36 includes a light-emitting layer of an organic material or an organic compound, respectively. The light-emitting layer may be part of a layer stack of a plurality of layers, wherein layers of the layer stack contain different organic compounds.

The light-emitting diode 36 is electrically contacted using conductive traces 38a, 38b. The conductive traces 38a, 38b are respectively arranged between two light sensors 34b, 34c or 34f, 34g, respectively. The conductive traces 38a, 38b connect the light-emitting diode 36 to terminal contact faces or terminal pads 40a, 40b, respectively, arranged at the sides of the light sensors 34c, 34g, facing away from the light-emitting diode 36. The terminal pads 40a, 40b are, for example, contacted using bond wires. Alternatively, from the terminal pads 40a, 40b through-hole conductors lead to the surface 42 of the Si substrate 30 facing away from the light sensors 34a, . . . , 34h and the light-emitting diode 36. At the surface 42 of the Si substrate 30 then preferably further terminal pads are implemented provided for a flip-chip mounting of the chip or the Si substrate 30, respectively, to a further substrate, for example a printed circuit board.

Corresponding conductive traces and terminal pads are preferably also provided for the light sensors 34a, . . . , 34h, not illustrated, however, in FIG. 1 for the purpose of a clear illustration.

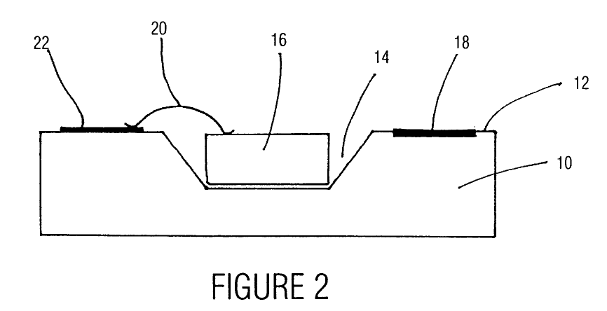

One advantage of the inventive opto-electronic device is that the light-emitting diode 36 may comprise a very low building height. Preferably, it comprises a building height of approximately 150 nm to 160 nm. A semiconductor light-emitting diode typically comprises a building height which is greater by several orders of magnitude and emits light at the macroscopic side faces. A direct radiation of light from the semiconductor light-emitting diode to the surrounding light sensors is, for example, prevented in the conventional opto-electronic device illustrated above with reference to FIG. 2 by the arrangement of the light-emitting diode in a recess 14.

In contrast to that, the light-emitting diode 36 of the opto-electronic device according to the present invention has such a low building height that it only emits very little light at its edges in the lateral direction. A direct radiation of light from the light-emitting diode 36 to the light sensors 34a, . . . , 34h is further preferably reduced or prevented by a suitable formation of the edges of the light-emitting diode. A suitable formation of the edges is, for example, an arrangement of narrow conductive traces or corresponding metallization structures between the light-emitting diode 36 and the neighboring or adjacent light sensors 34a, . . . , 34h, respectively. These conductive traces or metallization structures then present a kind of barrier preventing a straight propagation of light from the light-emitting diode 36 to one of the light sensors 34a, . . . , 34h. Alternatively, these barriers are formed of semiconductor oxide or are further made higher by a passivation layer applied over the conductive traces.

An alternative arrangement for reducing scattered light or a direct radiation of light from the light-emitting diode 36 onto the light sensors 34a, . . . , 34h, respectively, is the arrangement of the light-emitting diode 36 in a depression or recess, respectively, in the surface 32 of the Si substrate 30. In contrast to the conventional opto-electronic device illustrated above with reference to FIG. 2, however, a substantially lower depth of the recess is sufficient to reduce a radiation of scattered light from the light-emitting diode 36 onto the light sensors 34a, 34h in a sufficient way. Preferably, the depth of the recess is at least as great as the building height of the light-emitting diode 36. Again preferably, the depth of the recess is only a few to some μm.

The inventive opto-electronic device illustrated with reference to FIG. 1 is monolithically or integrally integrated, respectively. In the conventional opto-electronic device illustrated above with reference to FIG. 2, a completely generated and functional light-emitting diode 16 is inserted into the depression 14 of the substrate 10. In contrast to that, the light-emitting diode 36 of the inventive opto-electronic device is only generated at the surface 32 of the Si substrate 30. For this purpose, one or several optically active or light-emitting layers, respectively, are generated one after the other from an organic material or an organic-chemical substance, electrically conductive layers and, if applicable, further layers having predetermined electrical or optical characteristics. None of the materials applied to the surface 32 of the substrate 30 in layers for forming the light-emitting diode 36 has the function or effect of a light-emitting diode before the application. The light-emitting diode 36 is thus only generated on the surface 32 of the Si substrate 30. The light-emitting diode 36 is integrally and inseparably connected to the Si substrate 30. It may be not easily be separated from the Si substrate 30 without destroying its function. The function-maintinaing separation of the light-emitting diode 36 from the Si substrate 30 would only be possible with an extreme technological effort. For example, the Si substrate 30 might be removed by etching from the back side of the light-emitting diode 36. Here, the Si substrate 30 would be destroyed, however.

One application for the inventive opto-electronic device illustrated with reference to FIG. 1 is an angle of rotation sensor for detecting an angle of rotation. For this purpose, an optical device is arranged opposing and preferably in parallel to the surface 32 of the Si substrate 30. The optical device is rigidly connected to an application that may be rotated around an axis with relation to the opto-electronic device which is preferably substantially perpendicular to the surface 32 of the Si substrate 30 and further preferably arranged substantially in the middle of the light-emitting diode 36. The optical device reflects, diffracts or directs light in any other way from the light-emitting diode 36 onto the light sensors 34a, . . . , 34h.

The optical device comprises an optical characteristic which has the consequence that not all light sensors 34a, . . . , 34h receive light of the same intensity. The optical device preferably includes an optical grating or a grating structure, respectively, at which the light from the light-emitting diode 36 is diffracted by an interference. The diffracted light comprises intensity maxima in different solid angle ranges separated from each other by intermediate intensity minima. The solid angle ranges in which the intensity maxima and thus the intensity distribution on the light sensors 34a, . . . , 34h occur are dependent on the angular position of the optical grating relative to the opto-electronic device. From the light intensities received from the individual light sensors 34a, 34h, the angular position of the optical grating may thus be concluded.

The evaluation of the light intensities received from the light sensors 34a, . . . , 34h or the measurement signals generated by the light sensors 34a, . . . , 34h, respectively, is preferably performed by a logic circuit which is in particular preferably also integrated or integrally implemented, respectively, with the light sensors 34a, . . . , 34h and the light-emitting diode on the Si substrate 30. The logic circuit determines the angular position of the optical grating with relation to the opto-electronic device from the measurement signal of the light sensors 34a, . . . , 34h representing the received intensities. This angular position is preferably output in the form of an analog or digital electrical signal.

Instead of a diffraction grating, the optical device alternatively includes one or several other structures which direct light from the light-emitting diode 36 onto the light sensors 34a, . . . , 34h in a way which depends on the angular position of the optical device in relation to the opto-electronic device.

In deviation from the embodiment illustrated above with reference to FIG. 1, the inventive opto-electronic device alternatively comprises several light-emitting diodes or another number of light sensors. The light-emitting diode or the plurality of light-emitting diodes and the light sensor or the plurality of light sensors comprise any shape and any arrangement suitable for the intended application of the opto-electronic device.

For detecting a linear coordinate or a linear movement of an object or an optical device in relation to the opto-electronic device, the light sensors and one or several light-emitting diodes are preferably arranged in a linear way. For detecting a distance coordinate perpendicular to the surface of the substrate based on the intensity of reflected light, the opto-electronic device preferably comprises one single light sensor and one single light-emitting diode.

For detecting simple geometric images, the opto-electronic device preferably comprises a plurality of light sensors arranged in an array. One or several light-emitting diodes 36 are also arranged in the array or at its edge. For the detection of simple geometric images or also for other applications, the opto-electronic device may be combined with a mapping optical system of one or several mirrors or lenses.

Apart from intensity and direction or position dependence of the intensity, respectively, on an array of light sensors also the polarisation of light may be evaluated in order to determine a location, an alignment or an angular position, respectively, a distance, a size or another characteristic of the optical device or a light-reflecting object.

Preferably, the light sensor or the plurality of light sensors and the light-emitting diode or the plurality of light-emitting diodes are arranged on the same surface of a substrate and thus substantially coplanar to each other. Alternatively, the light sensor or the plurality of light sensors and the light-emitting diode or the plurality of light-emitting diodes are arranged on a curved surface of a substrate or on two or several non-parallel surfaces. For example, the light sensors are arranged at a surface of the substrate at which usually devices are formed, wherein the light-emitting diode or the plurality of light-emitting diodes are arranged at a lateral surface arranged in a right angle to the first surface. This is possible in particular as the light-emitting organic layer and the further layers of the light-emitting diodes may be generated independent of the crystallographic characteristic or of a layer structure of a semiconductor substrate.

In the following, a manufacturing of an inventive opto-electronic device according to a preferred embodiment is described. The starting point is an Si wafer or an Si substrate 30, respectively. The Si substrate 30 comprises the typical specifications which a substrate for light sensors or light-sensitive sensors, respectively, and for the corresponding semiconductor manufacturing process for the manufacturing of light sensors has to have. Preferably, it is in particular a high-impedance Si wafer. Alternatively, any substrate may be used preferably comprising a semiconductor material.

For the generation of the light sensors 34a, . . . , 34h and the light-emitting diode 36 using masking and lithography methods respective lateral areas are defined.

In the Si substrate 30 the light sensors 34a, . . . , 34h are generated according to the conventional semiconductor manufacturing technology by the implantation or in-diffusion of dopants. The area for the light-emitting diode 36 to be produced later is preferably kept free.

The generation of the light sensors 34a, . . . , 34h of the inventive opto-electronic device is preferably performed in CMOS technology. Alternatively, another technology may be used.

The light-emitting diode 36 is generated by the application of the corresponding basic materials. In particular, an optically active or light-emitting layer, respectively, of an organic material or an organic-chemical compound, respectively, is generated. Alternatively, a layer system of organic materials is generated, wherein one or several layers of the layer system are provided for a light emission. The generation of the layers of the light-emitting diode 36 is performed in an in-line fabrication facility. For this purpose, the Si substrate 30 is transferred into process-compatible manufacturing for the organic light-emitting diode 36. The organic light-emitting diode or the light-emitting diode 36 comprising the light-emitting organic layer, respectively, is generated in the free space on the surface 32 of the Si substrate 30 which was left free in the generation of the light sensors 34a, . . . , 34h.

Only after the generation of the light-emitting diode 36 in the OLED manufacturing facility (OLED=organic light-emitting diode) is the metallization required for a wiring of the circuit or the opto-electronic device, respectively, and for contacting the light-emitting diode 36 and the light sensors 34a, . . . , 34h applied. The metallization is preferably generated by sputtering using a corresponding target. The generation of the metallization thus presents one of the last working steps. The metallization is laterally structured by a suitable etching process in order to generate wiring conductive traces.

The completed circuit or the completed opto-electronic device, respectively, is provided with a thin film passivation the passivation is opened at the respective locations in order to form terminal pads. Alternatively, the passivation is directly applied using a so-called shadow mask.

The described manufacturing is preferably performed on wafer level. Even before dicing the wafer into individual opto-electronic devices, a testing of the completed circuits in the wafer arrangement is performed. This testing is preferably performed according to the standard process on a conventional wafer prober. Here, the opto-electronic devices of the wafer are contacted using so-called probe cards. The inventive opto-electronic device, in contrast to the conventional opto-electronic device described above with reference to FIG. 2, is completed and completely functional not only after dicing and bonding but already before dicing, i.e. still in the wafer arrangement. The inventive opto-electronic device is thus preferably tested with regard to its complete functionality, i.e. apart from its electric characteristics also the optical or electro-optical characteristics, respectively, of each individual opto-electronic device of the wafer are detected or measured, respectively. For this purpose, preferably optical devices or corresponding patterns or structures, respectively, are arranged opposite the opto-electronic devices of the wafer.

After the test of the opto-electronic devices of the wafer defective opto-electronic devices are designated by marking or inking, respectively, or entered into a wafer map and discarded directly after dicing.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. An opto-electronic position or angle detector, comprising:
a substrate;
a light-emitting diode having a light-emitting layer of an organic material;
a plurality of light sensors arranged laterally adjacent to the light-emitting diode,
wherein the light sensors and the light-emitting diode are monolithically integrated with the substrate; and
an optical device arranged opposite the light sensors and the light-emitting diode for directing light emitted from the light-emitting diode to the light sensors, wherein a characteristic of the light received from the light sensors is dependent on the location or the alignment or of a characteristic of the optical device.

2. The opto-electronic position or angle detector according to claim 1, wherein the light sensor and the light-emitting diode are arranged at a surface of the substrate.

3. The opto-electronic position or angle detector according to claim 2, further comprising
a conductive trace for contacting the light sensor or the light-emitting diode; and
a passivation layer covering a part of the conductive trace.

4. The opto-electronic position or angle detector according to claim 3, wherein the light-emitting layer of the light-emitting diode is thinner than the passivation layer.

5. The opto-electronic position or angle detector according to claim 1, wherein the light sensor is provided for receiving a light signal which is generated by the light-emitting diode and directed from an optical angle detector to the light sensor.

6. The opto-electronic position or angle detector according to claim 1, comprising a plurality of light-emitting diodes monolithically integrated with the substrate and respectively comprising a light-emitting layer of an organic material.

7. The opto-electronic position or angle detector according to claim 1, wherein the light sensor includes a photodiode or a phototransistor.

8. The opto-electronic position or angle detector according to claim 1, wherein the surface of the substrate is implemented such that a radiation of scattered light from the light-emitting diode to the light sensor is reduced or prevented.

9. The opto-electronic position or angle detector according to claim 8, wherein the light-emitting diode is arranged in a recess in the surface of the substrate.

10. The opto-electronic position or angle detector according to claim 1, including an optical grating for diffracting light by means of interference.

11. An opto-electronic position or angle detector, comprising:
a substrate;
a light-emitting diode having a light-emitting layer of an organic material;
a plurality of light sensors arranged laterally adjacent to the light-emitting diode;
wherein the light sensors and the light-emitting diode are monolithically integrated with the substrate; and
an optical device movably arranged opposite the substrate with regard to the position or angle to be detected, the optical device being arranged opposite the light sensors and the light-emitting diode for directing light emitted from the light-emitting diode to the light sensors, wherein the intensity, the direction or the polarization of the light received from the light sensors is dependent on the location or the alignment of the optical device.
